(19) United States
(12) Patent Application Publication
(10) Pub. No.: US 2011/0006858 A1
(43) Pub. Date: Jan. 13, 2011

(54) Multi-Source Spatial Power Amplifier

(75) Inventor: Jean-Philippe Fraysse, Toulouse (FR)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: THALES, NEUILLY/SUR/SEINE (FR)

(21) Appl. No.: 12/921,444

(22) PCT Filed: Feb. 26, 2009
(86) PCT No.: PCT/EP2009/052300

§ 371 Date: Sep. 8, 2010

(30) Foreign Application Priority Data
Mar. 11, 2008 (FR) 08 01324

(51) Int. Cl. H01P 5/12; H03F 3/68

(52) U.S. Cl. 333/137; 330/124 R

(57) ABSTRACT

An amplification device combining a number of amplifier modules operating in the microwave range includes: a power divider, having an input and at least two outputs, dividing an input microwave signal into a number of microwave signals; connecting waveguides used to propagate the microwave signals supplied by the power divider; at least one input transition element placed at the output of each connecting waveguide for receiving the microwave signal; an amplifier module connected to each of the input transitions with which to amplify the signal received by each of the input transitions; and an output transition element in planar technology connected to each of the amplifier modules with which to combine the amplified signals obtained from the amplifier modules.

The present invention relates to the field of semiconductor microwave amplifiers and, more particularly, power-combination systems. Of the various combination techniques, the field of the invention relates to spatial power combination systems.

The reduction in the output power of semiconductor elements combined with the increase in the operating frequency of the amplification devices has led to the need to combine a number of individual semiconductor amplifiers in order to achieve the output powers required by certain applications in the microwave field.

In cases where a large number of amplifiers is needed to achieve the desired power levels, the radial architecture is the best suited to address this kind of need. On the other hand, if a more limited number of amplifiers is sufficient, other combination techniques may be more favorable in terms of implementation, performance and footprint.

The current power combination systems based on tree-structured line or waveguide architectures do not make it possible to effectively combine individual amplifiers in a confined environment with a rectangular waveguide output interface able to cooperate with the devices downstream.

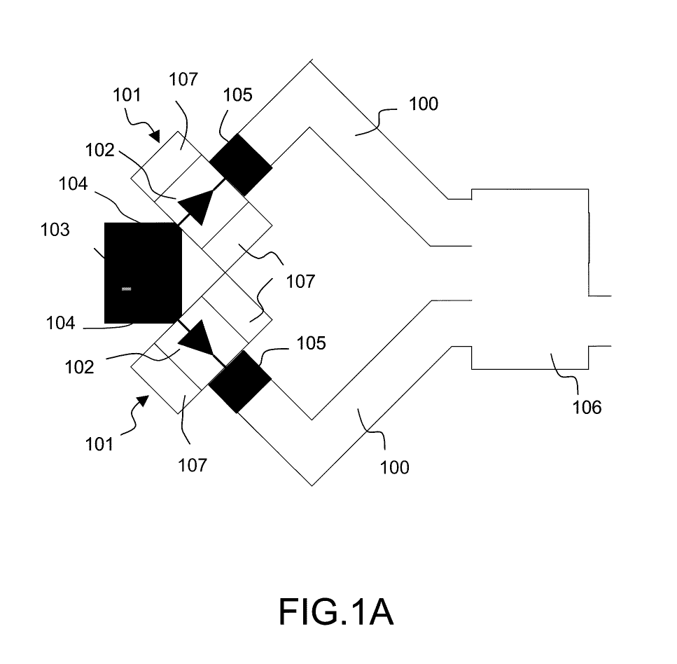

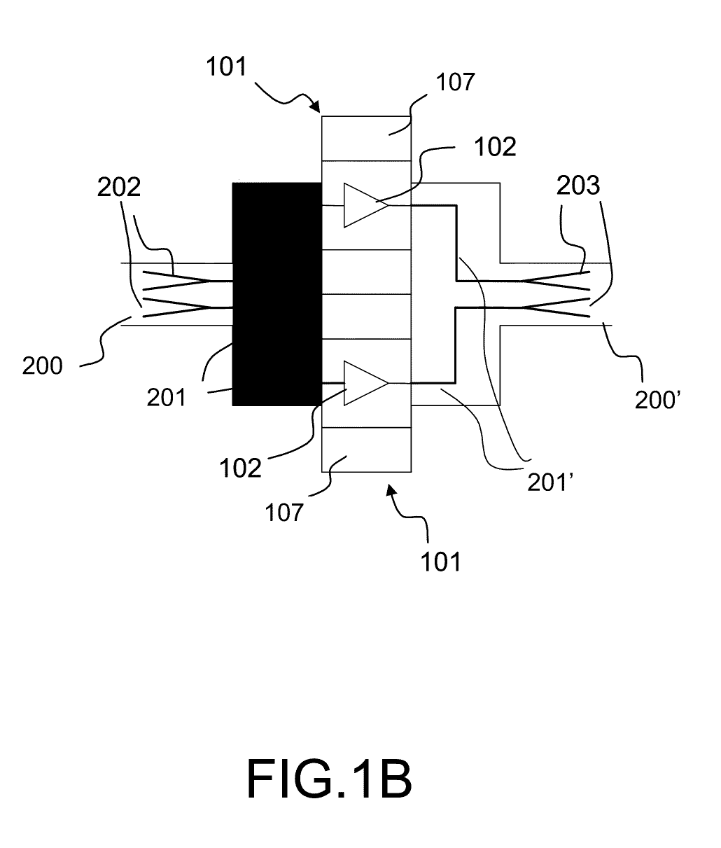

An exemplary power combination device based on a tree structure for a Ka band application is presented in FIG. 1A. It uses:
at the input, a power divider 103 in planar technology with microstrip line ports to limit the footprint;
two amplifier modules 101 with microstrip line ports each comprising an amplifier 102 and biasing circuits 107;
a hybrid coupler 106 in rectangular waveguide technology to minimize the combination losses;
two transitions 105 to switch from the microstrip propagation mode to the rectangular waveguide propagation mode;
rectangular waveguide sections 100 for connecting the amplifier modules 101 to the hybrid coupler 106.

In this example, in order to minimize the length of the microstrip lines 104 at the output of the power divider 103, a choice has been made to skew the structure, by positioning the two amplifier modules 101 perpendicularly to one another. This solution has the advantage of reducing the length of the microstrip lines 104 at the output of the power divider 103 in order to reduce the insertion losses of the divider, but nevertheless presents the drawback of being bulky because of the length of the rectangular waveguide sections 100 and because of the size of the hybrid coupler 106 in rectangular waveguide technology.

The use of this type of combination at high frequencies, over 30 GHz for example, also presents other drawbacks. Notably, the phase-matching of the amplifier modules is difficult and the combination losses are not inconsiderable because of the build up of the insertion losses from the numerous elements passed through by the signal and the fact that these losses increase as the operating frequency is raised.

The weaknesses of this architecture are emphasized for an embodiment combining four amplifiers.

The spatial combination technique as developed in the patent U.S. Pat. No. 5,736,908 is an alternative solution. It is characterized in that the amplification device comprises a number of amplifier modules, arranged on decks, stacked in a rectangular waveguide. The input signal generated by a single source is distributed over the amplifier modules by virtue of the spatial distribution of the energy of the signal and it is recombined at the output once amplified according to the same principle. This solution makes it possible to perform in a single step on the one hand the combining of the signals and on the other hand the transitions between the planar technology lines and the rectangular waveguide output interface. By virtue of these features, it does make it possible to minimize the combination losses and the footprint of the structure. However, this combination technique, as described in the state of the art, has drawbacks and limitations.

In practice, the number of decks stacked in a rectangular waveguide and the number of associated amplifiers on one and the same deck decrease with the reduction in the size of the rectangular waveguides dictated by the increase in operating frequency.

It is thus difficult to envisage being able to place more than one deck in a Q band WR22-standardized rectangular waveguide. Furthermore, in this particular case, represented in FIG. 1B, the width of the standardized rectangular waveguide 200, 200′ is much smaller than the width of an amplifier module 101, the latter comprising an amplifier 102 and the biasing circuits 107 including the decoupling capacitors and the biasing ports.

The result of this is that it is necessary to use long link lines in planar technology 201, 201′ in order to link the ports of the amplifier modules 101 to the transitions 202 of the spatial divider excited by a single source and to the transitions 203 of the spatial combiner. The significant losses induced by these lines in these frequency bands are leading to a diminished interest in spatial power combination for reducing combination losses.

For operating frequencies below the Q band, as, for example, in the X band or in the Ku band, since the rectangular waveguides are bigger, a number of decks can be arranged in a standardized rectangular waveguide and the lengths of the lines linking the amplifiers are reduced. However, in these frequency bands, this technique, as described in the state of the art, also has some drawbacks, notably:
the input is in rectangular waveguide technology and not planar technology;
the decks are often thin in order to be able to stack a number thereof in a rectangular waveguide. This can make heat management difficult;
the amplifiers are placed in the propagation axis of the rectangular waveguide which means having to use additional planar technology lines to link the amplifiers to the transitions. Although the losses of the planar technology lines decrease with decreasing frequency, it is still advantageous to minimize their contribution to the combination losses by reducing their lengths;
since the amplifiers are not in separate cavities, managing the instability risks may prove difficult;
the need to place decoupling capacitors as close as possible to the amplifiers in order to stabilize them conflicts with the need to reduce the width of the amplifier modules in order to minimize the length of the planar lines linking the ports of the amplifiers to the ports of the divider and of the combiner.

One aim of the invention is to mitigate the abovementioned drawbacks.

The invention proposes a multiple-source spatial amplification device that sends the components deriving from the division of the input microwave signal into connecting waveguides, the components being amplified and combined in a single output waveguide.

Advantageously, the amplification device combines a number of amplifier modules operating in the microwave range:

Advantageously, the device comprises:
a power divider, having an input and at least two outputs, dividing an input microwave signal into a number of microwave signals;
connecting waveguides able to cooperate with the outputs of the power divider, used to propagate the microwave signals supplied by the power divider;
at least one input transition element in planar technology placed at the output of each connecting waveguide for receiving the microwave signal that is propagated in the connecting waveguide;
an amplifier module connected to each of the input transitions with which to amplify the signal received by each of the input transitions and comprising at least one amplifier;
an output transition element in planar technology connected to each of the amplifier modules and able to cooperate with an output waveguide common to all the output transition elements with which to combine the amplified signals obtained from the amplifier modules, these combined signals forming the output microwave signal.

Advantageously, each amplifier module and its input and output transition elements are on one and the same plane.

Advantageously, the amplifier modules and their input and output transition elements are on planes that are parallel to one another.

Advantageously, the transition elements are finned lines configured to provide electrical matching between the connecting waveguides, the amplifier modules and the output waveguides.

Advantageously, the device comprises at least two external half-shells forming a part of the output waveguide, on which at least one amplifier module is in contact in order to favor the heat exchanges between the amplifier modules and the exterior of the device.

Advantageously, the axis of the amplifier modules is perpendicular to the axis of propagation of the microwave signal resulting from the combined signals.

Advantageously, the input of the divider can be produced in metal waveguide or planar technology.

Advantageously, the connecting waveguides and the output metal waveguide are rectangular or circular metal waveguides.

Advantageously, each connecting waveguide is equipped with an element for adjusting the phase of the signal being propagated in each connecting waveguide.

Advantageously, the input and output transitions associated with an amplifier module are implemented on one and the same printed circuit.

Advantageously, the input and output transition elements associated with an amplifier module and the power divider are implemented on one and the same printed circuit.

Advantageously, the output transitions are separated inside the output waveguide by a metal wall.

Advantageously, the metal wall is extended by a resistive film.

Advantageously, the device makes it possible to reduce the combination and division losses.

Advantageously, the structure of the device is compact.

Advantageously, the device has phase adjusting elements in the connecting waveguides in order to compensate for the phase dispersion of the amplifier modules.

Advantageously, the device makes it possible to process high frequencies in the microwave domain, notably above 30 GHz.

Other features and advantages of the invention will become apparent from the following description, given in light of the appended drawings which represent:

FIG. 1A: a first amplification device with tree-structured architecture from the prior art;

FIG. 1B: a second amplification device with power spatial combination from the prior art, with a view of a single deck;

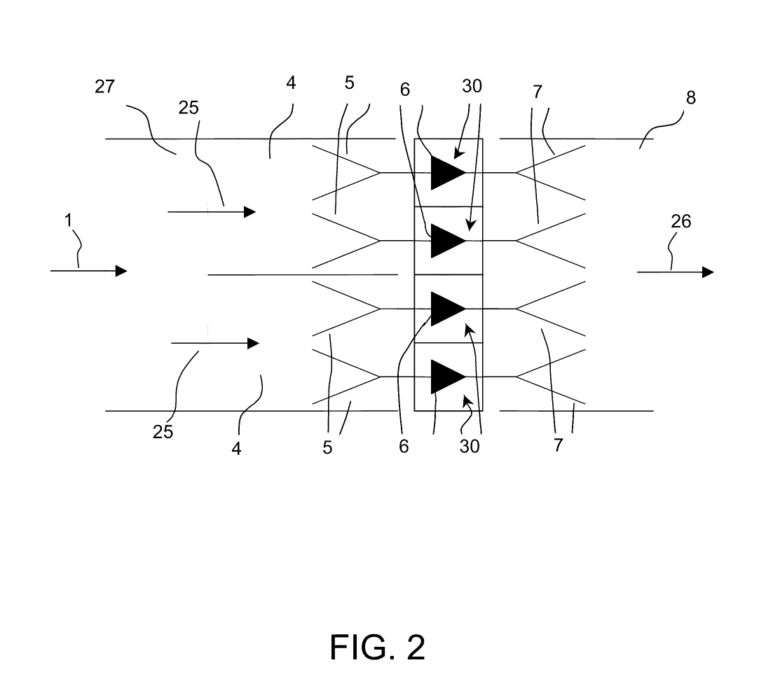

FIG. 2: a schematic diagram of a multiple-source spatial amplification device according to the invention;

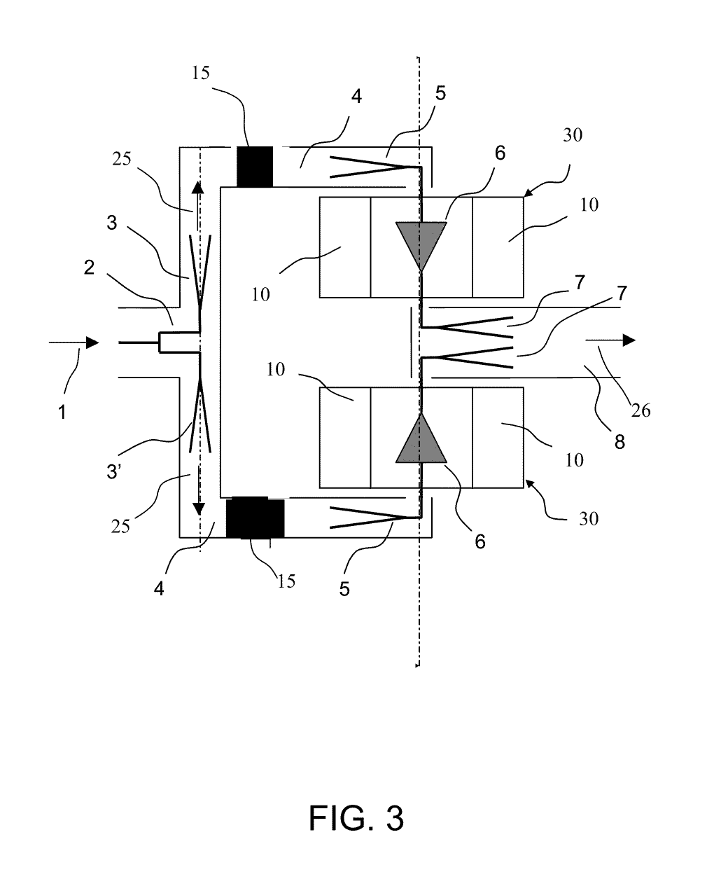

FIG. 3: a multiple-source spatial amplification device of the invention;

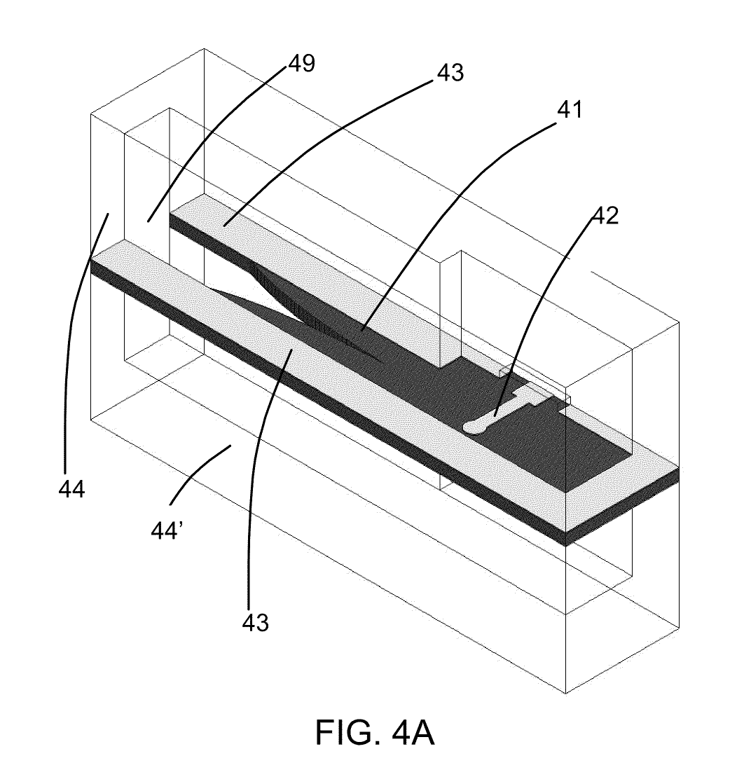

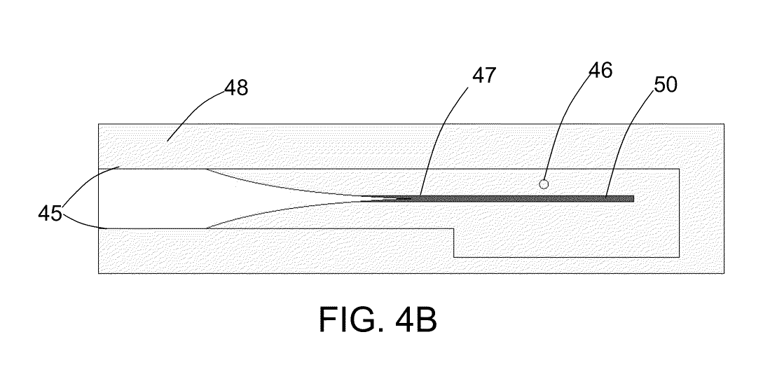

FIG. 4A: a view of an embodiment of a transition element, seen from the top side of the printed circuit;

FIG. 4B: a view of the embodiment presented in FIG. 4A, seen from the bottom side of the printed circuit;

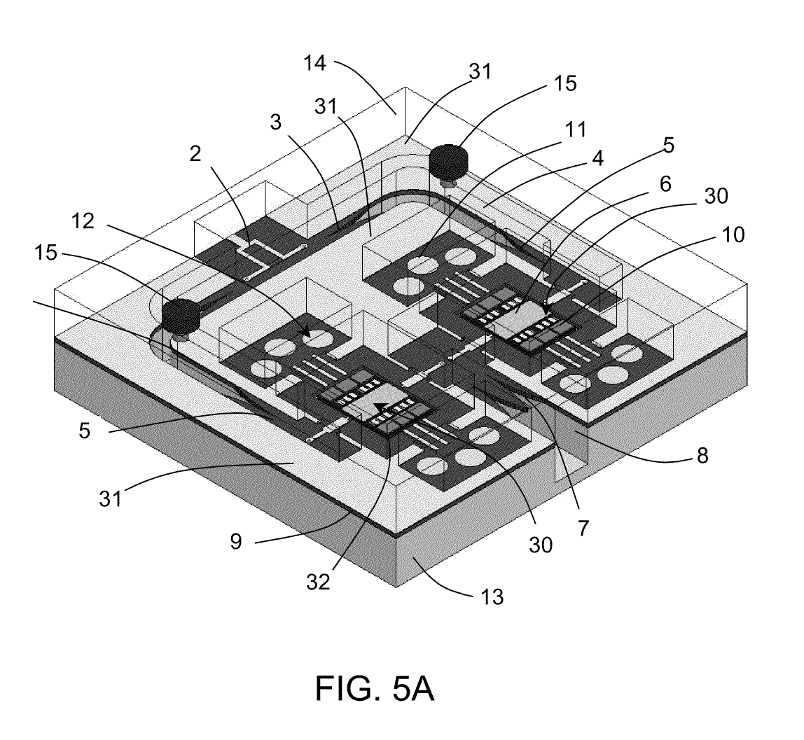

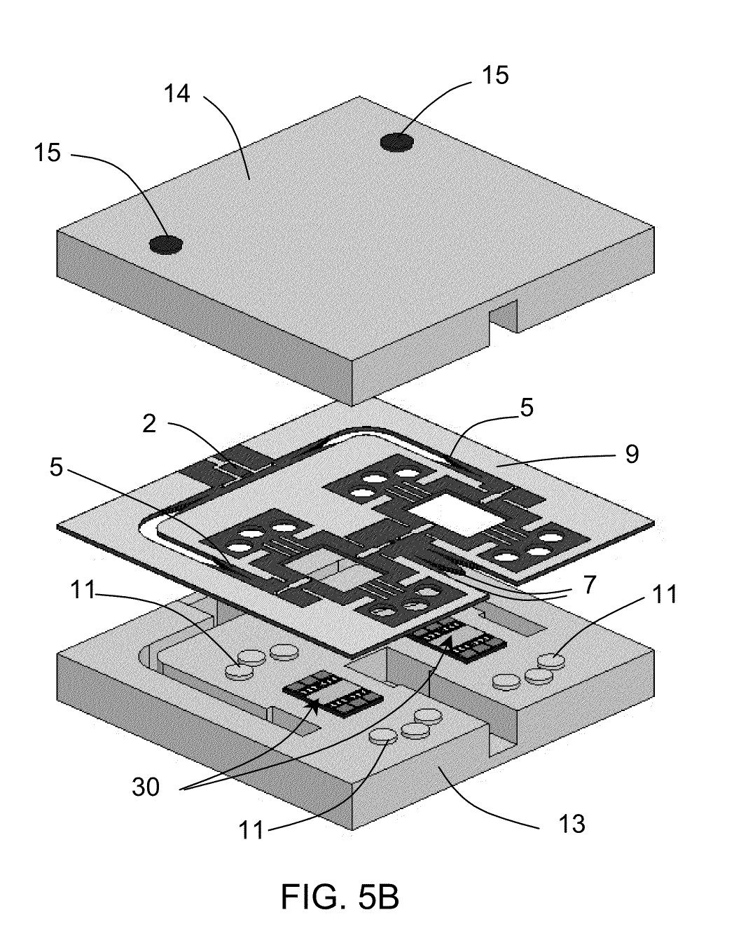

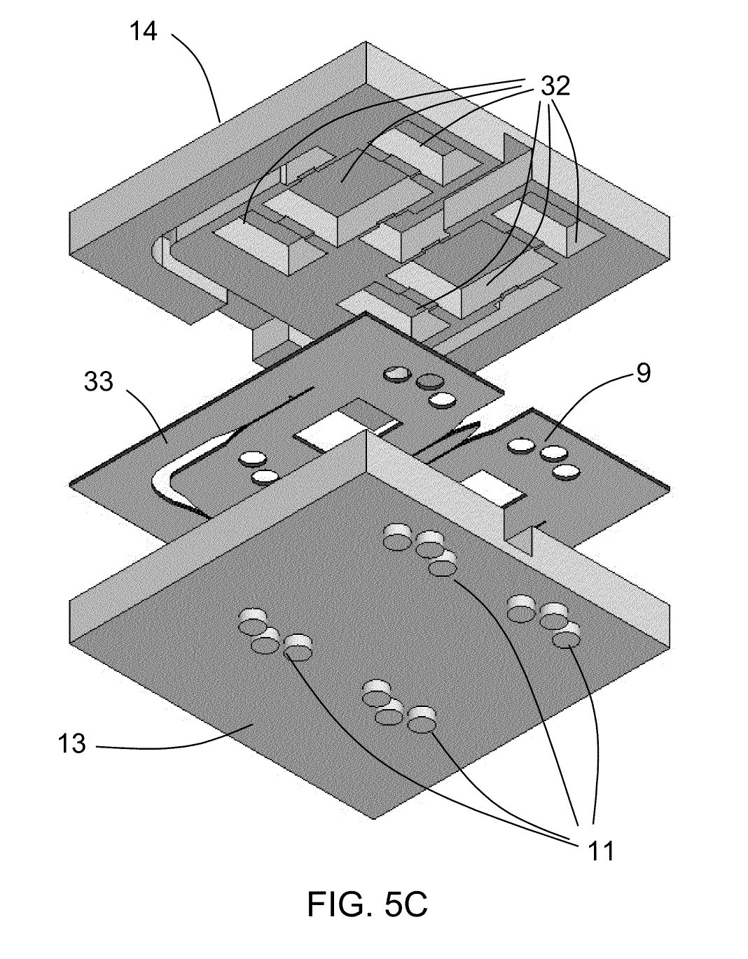

FIG. 5A: a first view of a first embodiment of the device comprising two amplifiers, with the top half-shell shown transparent;

FIG. 5B: an exploded view, seen from above, of the embodiment of the device of FIG. 5A;

FIG. 5C: an exploded view, seen from below, of the embodiment of the device of FIG. 5A;

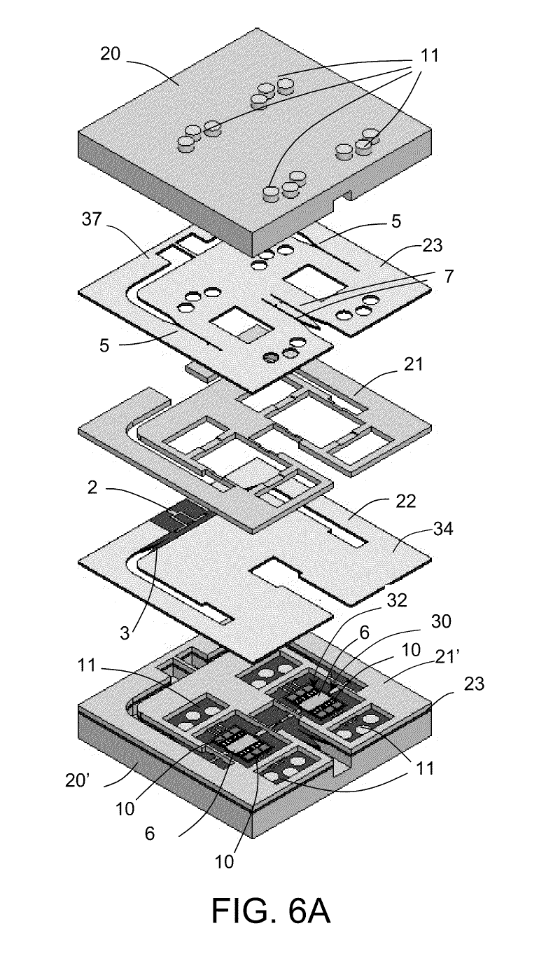

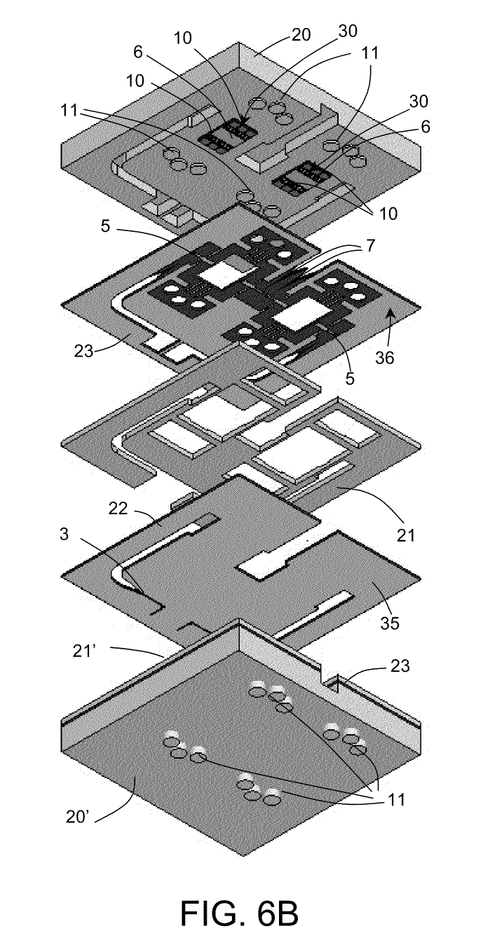

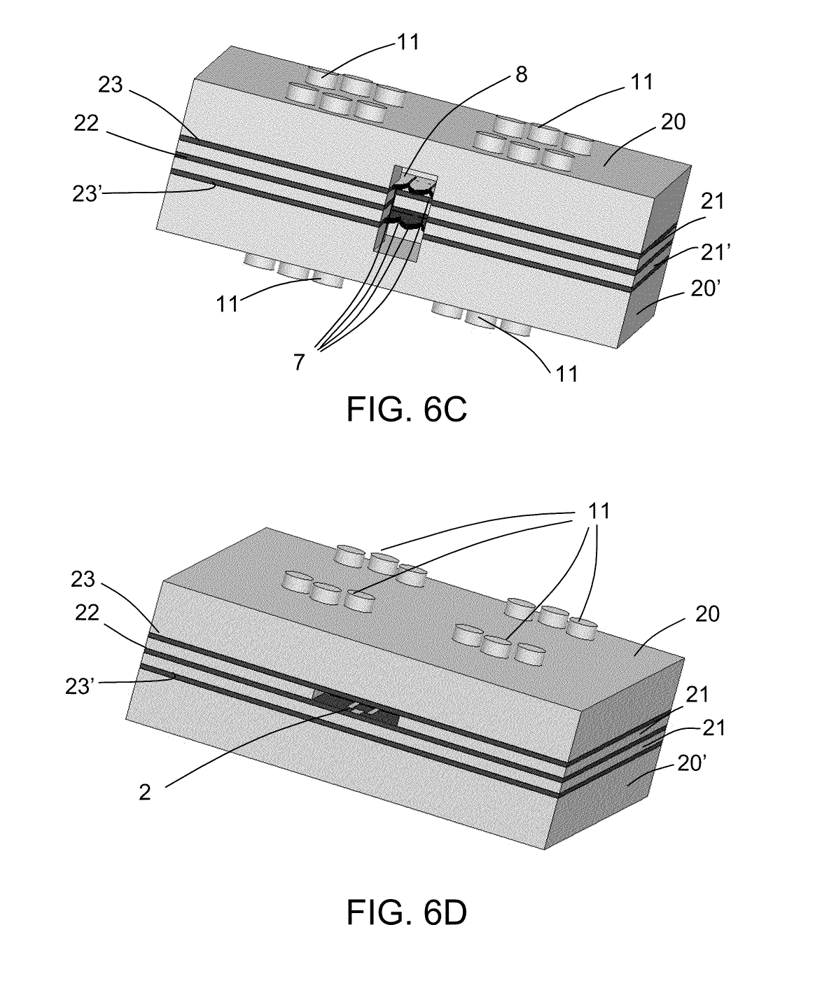

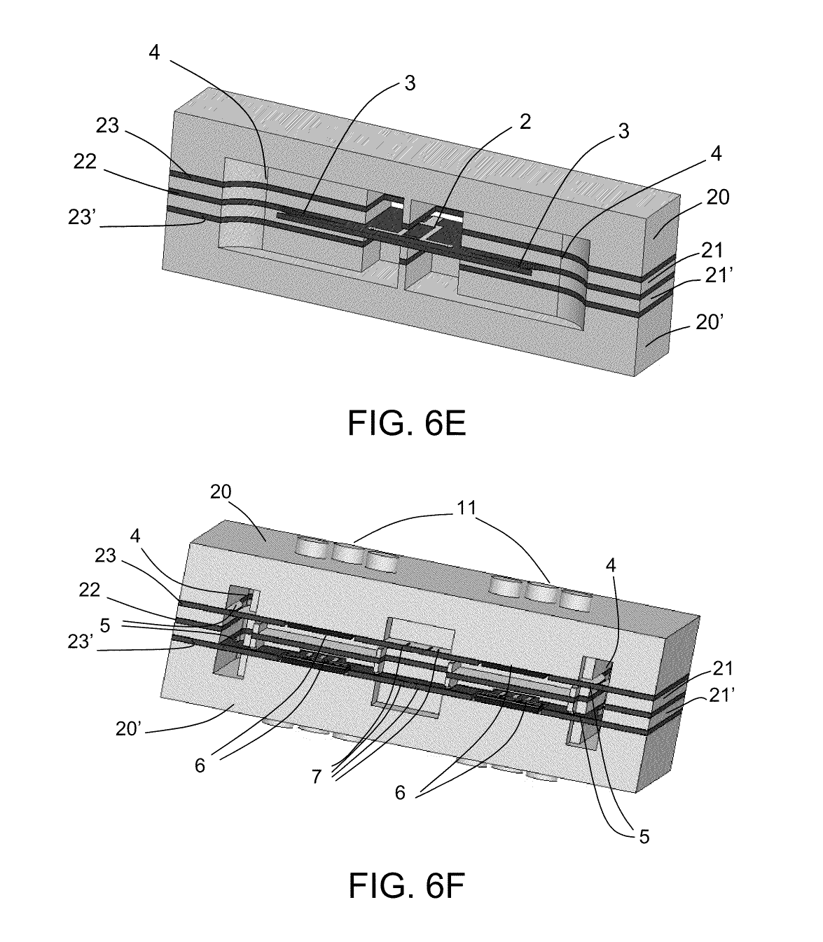

FIG. 6A: an exploded view, seen from above, of an embodiment of the device comprising four amplifiers;

FIG. 6B: an exploded view, seen from below, of the embodiment of the device of FIG. 6A;

FIG. 6C: a view, showing the combiner port, of the embodiment of the device of FIG. 6A, assembled;

FIG. 6D: a view, showing the divider port, of the embodiment of the device of FIG. 6A, assembled;

FIG. 6E: a cross-sectional view of the signal division part of the embodiment of the device of FIG. 6A, assembled;

FIG. 6F: a cross-sectional view at the level of the amplifier modules of the embodiment of the device of FIG. 6A, assembled;

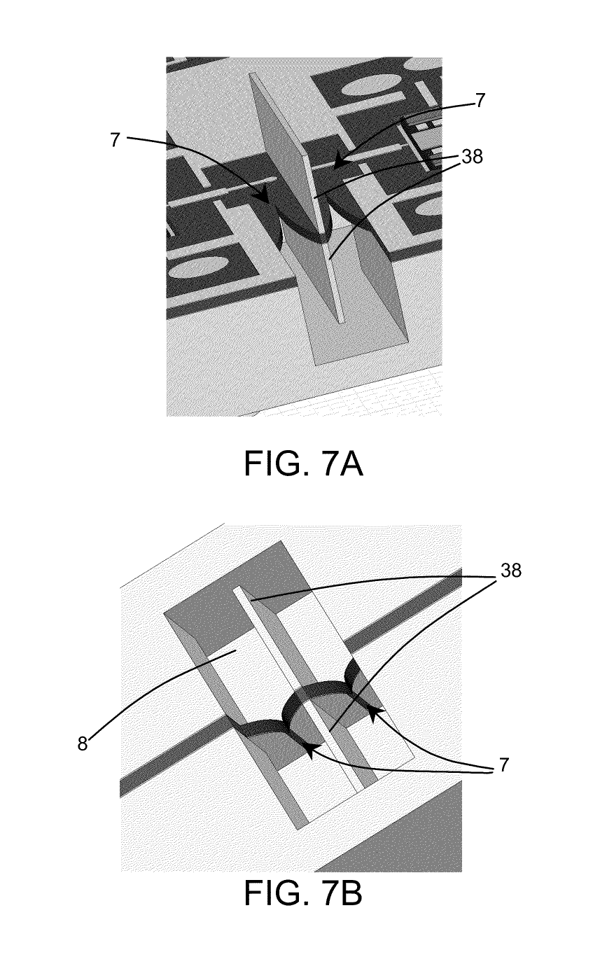

FIG. 7A: a view of an embodiment with a metal wall separating the two output transition elements;

FIG. 7B: a view of the embodiment presented in FIG. 7A with the top half-shell;

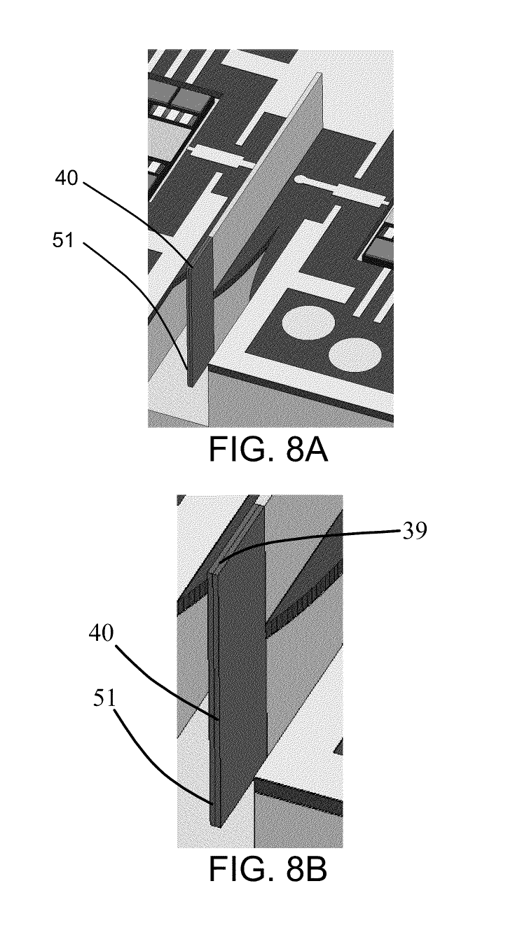

FIGS. 8A and 8B: two views of an embodiment in which the metal wall separating the two output transition elements is extended by a resistive film;

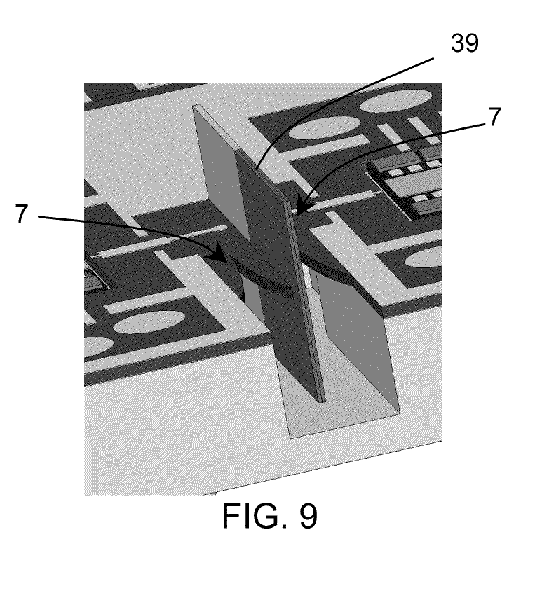

FIG. 9: a view of an embodiment in which a resistive film is incorporated between the two output transition elements;

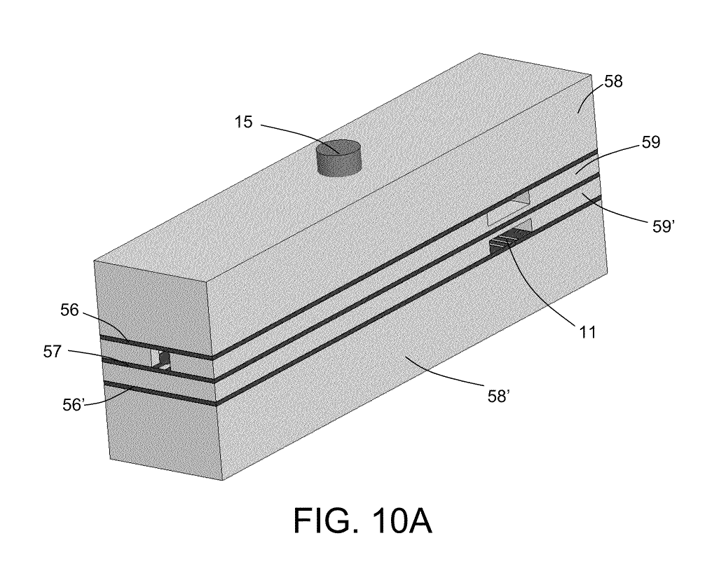

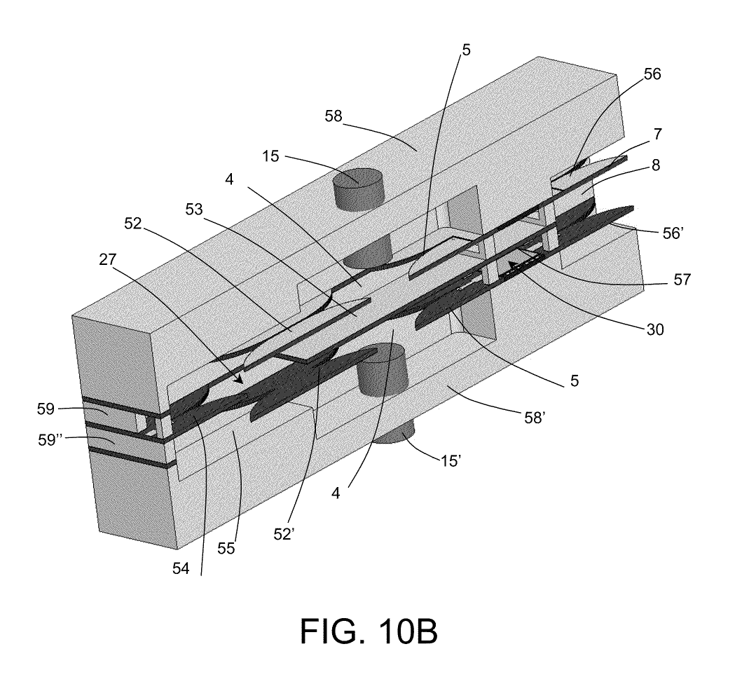

FIG. 10A: an external view, of an embodiment of the device comprising two stacked amplifier modules;

FIG. 10B: a cross-sectional view of the embodiment presented in FIG. 10A.

FIG. 2 represents a schematic diagram of a device according to the invention comprising four combined amplifier modules 30. The device represented comprises two connecting waveguides 4 preceded by a power divider 27. The power divider 27 is used to divide an input microwave signal 1 into two components 25 that are propagated in the two connecting waveguides 4. The power divider 27 can be in planar technology or, for example, in metal waveguide technology, such as a “septum divider”, a term that denotes a divider consisting of an input and two rectangular waveguide outputs. Generally in this type of divider, the two output waveguides are separated at the point of division by a thin wall (i.e. “septum”, to use the Latin term) which may be metallic or resistive.

In one embodiment, a divider 27 in planar technology is associated with two transitions that are not represented in FIG. 2, to ensure the change of propagation mode of the signal between a planar structure and a connecting waveguide 4. In each of the connecting waveguides 4, two input transition elements 5 in planar technology are used to distribute the components of the input microwave signal 25 in the amplification modules 30, each comprising at least one amplifier 6. The duly amplified signals are then transmitted via four output transition elements 7 in planar technology into an output waveguide 8 used to recombine the output microwave signal 26.

FIG. 3 represents one embodiment of a device according to the invention comprising a power divider 2, access to which is obtained via a microstrip-type input. The power divider 2 is used to divide the input microwave signal 1 into two components to illuminate the two rectangular connecting waveguides 4 through the two transitions 3, 3′. The signals are propagated in the connecting rectangular waveguides 4 from output transitions 3, 3′ of the divider to input transition elements 5 of the amplifier modules 30. In this embodiment, a transition 5 is placed at the output of each connecting waveguide 4.

The amplifier modules 30 each comprise an amplifier 6, biasing circuits with decoupling capacitors 10. The output transition elements 7 provide electrical matching between the amplifier modules 30 and the rectangular waveguide 8. In a preferred embodiment, the axis of the inputs and of the outputs of the two amplifier modules 30 is perpendicular to the axis of propagation of the output microwave signal 26. This arrangement makes it possible to reduce the length of the planar lines linking the amplifier modules 30 to the output transition elements 7 and to the input transition elements 6, so that the length of the lines is minimal. The combination losses and the division losses are thus minimized.

In another embodiment, the device according to the invention comprises phase adjusting elements 15 in the connecting waveguides 4 to control the relative phase between the signals 25 being propagated in the connecting waveguides 4 so as to ensure an in-phase recombination of these signals in the output waveguide 8 once amplified by the amplifier modules 30. This functionality makes it possible to minimize the combination losses by eliminating the losses induced by a phase imbalance in the combined signals.

In one embodiment, the phase adjusting elements 15 can be implemented by dielectric elements introduced into the connecting waveguides. The depths to which these dielectric elements are inserted into the connecting waveguides 4 then make it possible to act on the phases of the signals 25 being propagated in the connecting waveguides 4.

In other embodiments, the transitions can be replaced by a network of transitions and the amplifiers can be replaced by a network of amplifiers.

Moreover, the transition elements can be implemented with finned lines or slotted lines associated with microstrip lines. A number of transitions can be arranged on one and the same printed circuit so as to produce transition networks. The circuits can be produced on organic substrates such as RO4003™.

FIGS. 4A and 4B represent one embodiment of a transition element on a printed circuit 41 between two half-shells 44 forming a rectangular waveguide 49.

The two half-shells 44 are shown transparent. FIG. 4A and FIG. 4B respectively show the top side and the bottom side of the printed circuit 41. The metal planes 43 and 48 either side of the printed circuit 41 are linked by a set of metalized holes, not shown in FIGS. 4A and 4B, to provide electrical continuity between the half-shells 44 and 44′. On the bottom side, a progressive shortening of the distance separating the two internal edges 45 of the metal plane 48 is used to switch gradually from the propagation mode in the rectangular waveguide 49 to the slot propagation mode in the slot 47. The transition between the slot mode being propagated in the slot 47 and the microstrip mode being propagated between the line 42 and the metallization plane 48 is obtained by virtue of the slotted line 50 of length λ/4 terminated by a short circuit and of the metalized hole 46 linking the line 42 and the metal plane 48.

In the embodiment presented in FIGS. 4A and 4B, the printed circuit 41 is cut so as to eliminate all the parts of the printed circuit that lead to a degradation of the insertion losses of the transition element and that are of no use in observing the electrical and mechanical stresses of the transitions. The circuit is then cut between the two internal edges 45 of the metal plane 48.

FIG. 5A represents an embodiment of the invention combining two amplifiers 6. In this embodiment, a printed circuit 9 is inserted between a bottom half-shell 13 and a top half-shell 14. The top half-shell 14 is shown transparent in FIG. 5A.

The half-shells 13, 14 can be made of aluminum with a gold finish. The printed circuit 9 may be produced from an organic substrate such as RO4003™. The assembly of the two half-shells 13, 14 and of the printed circuit 9 forms two connecting waveguides 4 and the output waveguide 8. The printed circuit 9 comprises a microstrip power divider 2, the output transitions 3 of the power divider 2, the input 5 and output 7 transition elements and metallization planes 31. The metallization planes 31 either side of the printed circuit 9 are linked by a set of metalized holes in order to provide electrical continuity between the two sides of the printed circuit which are in contact with the two half-shells 13, 14. These metalized holes, and the wires used to connect the amplifier modules to the planar input and output transition elements and to the biasing ports are not represented in this figure or in the subsequent figures. The biasing voltages of the amplifiers 6 are transmitted via biasing ports 11 and decoupled by decoupling capacitors 10. Two phase adjusting elements 15 are used to control the phases of the signals combined in the output waveguide 8. The amplifiers and the decoupling capacitors are mounted on an element with high thermal conductivity 32, and they form the amplifier module 30 for this embodiment.

In another embodiment, the amplifier module 30 consists only of the amplifier. The amplifier modules 30 are then placed directly in contact with the body of the amplification device, the body of the device comprising the bottom half-shell 13. This arrangement offers the advantage of favoring heat exchanges between the amplifier modules 30 and the exterior of the device.

FIG. 5B is an exploded view from above of the embodiment of the invention presented in FIG. 5A with the printed circuit 9, the top half-shell 14 equipped with phase adjusting elements 15 and the bottom half-shell equipped with the amplifier modules 30 and the biasing ports 11. This figure shows the simplicity with which this embodiment of the invention can be assembled by virtue of a stacking of the half-shells 14, 15 and of the circuit 9 and of the implementation on a single printed circuit 9 of the power divider 2 and of the input 5 and output 7 transition elements.

FIG. 5C is an exploded view from below of the embodiment of the invention presented in FIG. 5A. It represents the biasing ports 11 oriented toward the outside of the bottom half-shell 13, and the bottom metal plane 33 of the circuit 9 and the cavities 32 of the top half-shell 14 that are necessary to accommodate the amplifier modules 30 and the biasing ports 11.

FIG. 6A and FIG. 6B represent two exploded views of an embodiment of the invention combining four amplifiers, respectively a plan view and a view from below. In this embodiment, three circuits 22, 23, 23′, two half-shells 20, 20′ and two gratings 21, 21′ are stacked. The assembly of these elements forms two connecting waveguides and the output waveguide. In FIGS. 6A and 6B, a half-shell 20′, a circuit 23′ and a grating 21′ are assembled and the two half-shells 20, 20′ are equipped with the amplifier modules 30 and the biasing ports 11. The half-shells 20, 20′ and the gratings 21, 21′ can be made of aluminum with a gold finish. The circuits 22, 23, 23′ can be produced from a substrate such as RO4003™. The circuit 22 comprises a microstrip power divider 2, the output transitions of the power divider 3 and metallization planes 34, 35. The circuits 23, 23′ comprise the input 5 and output 7 transition elements and metallization planes 36, 37. The metallization planes either side of a circuit are linked by a set of metalized holes in order to provide electrical continuity between the two sides of a circuit in contact with the half-shells or the gratings. The biasing voltages of the amplifiers 6 are transmitted via biasing ports 11 and decoupled by decoupling capacitors 10.

In a variant embodiment, phase adjusting elements can be added to control the phases of the signals combined in the output waveguide.

In another variant embodiment, the amplifiers and the decoupling capacitors are mounted on an element with high thermal conductivity 32, these elements forming the amplifier module for this embodiment.

In another variant embodiment, the amplifier module can consist of just one amplifier. The amplifier modules 30 are placed directly in contact with the body of the amplification device, made up of the half-shells 20, 20′, in order to favor the heat exchanges between the amplifier modules 30 and the exterior of the device.

FIG. 6C and FIG. 6D represent two views of the embodiment of the invention assembled from the embodiments of FIGS. 6A and 6B. FIG. 6C represents a view from the side where the output waveguide 8 is situated with the output transition elements 7. FIG. 6D represents a view from the side where the power divider 2 is situated. These representations 6C and 6D show the three circuits 22, 23, 23′, the two gratings 21, 21′ and the two half-shells 20, 20′ assembled with the biasing ports 11.

FIG. 6E represents a cross-sectional view of the embodiment of the invention represented in FIGS. 6C and 6D at the level of the power divider 2. It represents the power divider 2 followed at the output by the two transitions 3 that are used to illuminate the connecting waveguides 4 via the components of the divided input microwave signal.

FIG. 6F represents a cross-sectional view of the embodiment of the invention presented in FIGS. 6C and 6D at the level of the amplifier modules. In each of the connecting waveguides 4, two input transition elements in planar technology 6 are used to distribute the components of the input microwave signal into the amplification modules 30. The duly amplified signals are then transmitted via four output transition elements in planar technology 7 into an output waveguide 8 that is used to recombine the output microwave signal. Each amplifier module 30 and its associated input 5 and output 7 transition elements in planar technology are placed on one and the same plane. The amplifier modules 30 are divided over two parallel planes, each plane comprising two amplifier modules 30.

In one embodiment, the transition elements 5 and 7 are finned lines configured to provide electrical matching between the connecting waveguides 4, the amplifier modules 30 and the output waveguide 8. The axis of the amplifier modules 30 is perpendicular to the axis of propagation of the microwave signal resulting from the combined signals. The amplifier modules 30 are placed directly in contact with the body of the amplification device in order to favor the heat exchanges between the amplifier modules and the exterior of the device by virtue of a facing arrangement of the amplifiers. The amplifier modules 30 can be insulated in separate cavities using the metallization planes of the circuit 22.

FIGS. 7A and 7B present another embodiment of the invention with views of the output waveguide with and without the top half-shell. The device according to the invention comprises, in this embodiment, elements 38 forming a separating metal wall separating the two output transition elements 7 from the output waveguide 8.

In another embodiment, the metal wall can be extended by a resistive surface in order to enhance the insulation between the combined amplifying pathways. In the embodiment presented in FIGS. 8A and 8B, the resistive film 39 is mounted on a circuit 51. The top half-shell is not represented in these figures. A circuit 40 with a size identical to that of the circuit 51 without resistive film is placed in contact with the circuit 51 in order to balance the structure. The circuits 50 and 51 can be made, for example, of alumina or AIN.

In another embodiment represented in FIG. 9, the resistive surface is directly incorporated in the wall separating the transition elements 7.

FIGS. 10A and 10B represent another embodiment of a device according to the invention combining two stacked amplifier modules. FIG. 10A and FIG. 10B are respectively an external view and a cross-sectional view of this embodiment. In this embodiment, three circuits 56, 56′, 57, two half-shells 58, 58′ and two gratings 59, 59′ are stacked. The assembly of these elements forms two connecting waveguides 4, the output waveguide 8 and an input waveguide 55. The two connecting waveguides are separated by metallization planes 53 either side of the substrate 57. The circuit 57 also comprises a transition 54 to provide matching between the microstrip port of the device and the input waveguide 55. The circuits 56, 56′ comprise the input transition elements 5 and the output transition elements 7, the biasing ports 11 of the amplifier modules 30 and finned line transition elements 52. The power divider 27 is implemented via the two finned line transitions 52 used to pick up the signal that is being propagated in the input rectangular waveguide 55 and illuminate the two stacked connecting waveguides 4. Two phase adjusting elements 15 are used to independently control the phases of the signals combined in the output waveguide 8.

This last embodiment can also be implemented in the embodiment of FIGS. 6A, 6B, 6C, 6D, 6E and 6F in order to be able to individually control the phase of the signals that are being propagated in the four connecting waveguides.

The solution proposed in this description can be used to combine two to four amplifier modules and even more depending on the operating frequency with:
very low combiner insertion losses so as not to degrade the added power efficiency of the device;
a rectangular waveguide output in order to be directly compatible with the interface of the circuits placed downstream;
an input in planar technology allowing better compatibility with the circuits placed upstream;
sufficient space around the amplifiers to be able to place the decoupling capacitors needed for the electrical stability of the amplifier;
a device that makes it easy to compensate for the phase dispersion of two amplifier modules in order to minimize the combination losses;
very good heat management to observe the spatial constraints on the semiconductor junction temperatures;
reduced footprint to minimize the weight of the equipment;
the possibility of placing the amplifiers in separate cavities so as to avoid the resonance and coupling problems;
low division losses;
ease of assembly that makes it possible to offer an inexpensive solution.

1. An amplification device combining a number of amplifier modules operating in the microwave range, comprising:
a power divider, having an input and at least two outputs, dividing an input microwave signal into a number of microwave signals;
connecting waveguides able to cooperate with the outputs of the power divider, used to propagate the microwave signals supplied by the power divider;
at least one input transition element in planar technology placed at the output of each connecting waveguide for receiving the microwave signal that is propagated in the connecting waveguide;
an amplifier module connected to each of the input transitions with which to amplify the signal received by each of the input transitions and comprising at least one amplifier; and
an output transition element in planar technology connected to each of the amplifier modules and able to cooperate with an output waveguide common to all the output transition elements with which to combine the amplified signals obtained from the amplifier modules, these combined signals forming the output microwave signal.

2. The amplification device as claimed in claim 1, wherein each amplifier module and its input and output transition elements are on one and the same plane.

3. The amplification device as claimed in claim 2, wherein said amplifier modules and their input and output transition elements are on planes that are parallel to one another.

4. The amplification device as claimed in claim 1, wherein said transition elements are finned lines configured to provide electrical matching between the connecting waveguides, the amplifier modules and the output waveguides.

5. The amplification device as claimed in claim 1, comprising at least two external half-shells forming a part of the output waveguide, on which at least one amplifier module is in contact in order to favor the heat exchanges between the amplifier modules and the exterior of the device.

6. The amplification device as claimed in claim 1, wherein the axis of the amplifier modules is perpendicular to the axis of propagation of the microwave signal resulting from the combined signals.

7. The amplification device as claimed in any claim 1, wherein the input of the divider is in metal waveguide technology.

8. The amplification device as claimed in claim 1, wherein said input of the divider is in planar technology.

9. The amplification device as claimed in claim 1, wherein said connecting waveguides and the output metal waveguide are rectangular or circular metal waveguides.

10. The amplification device as claimed in claim 1, wherein each connecting waveguide is equipped with an element for adjusting the phase of the signal being propagated in each connecting waveguide.

11. The amplification device as claimed in claim 1, wherein the input and output transition elements associated with an amplifier module are implemented on one and the same printed circuit.

12. The amplification device as claimed in claim 1, wherein the input transition elements associated with an amplifier module and the power divider are implemented on one and the same printed circuit.

13. The amplification device as claimed in claim 1, wherein said output transitions are separated inside the output waveguide by a metal wall.

14. The amplification device as claimed in claim 13, wherein said metal wall is extended by a resistive film.

15. The amplification device as claimed in claim 2, wherein said transition elements are finned lines configured to provide electrical matching between the connecting waveguides, the amplifier modules and the output waveguides.
